(19) United States
(12) Patent Application Publication
(10) Pub. No.: US 2013/0170125 A1
(43) Pub. Date: Jul. 4, 2013

(54) TERMINAL DEVICE

(71) Applicants: LENOVO (BEIJING) CO., LTD., Beijing (CN); BEIJING LENOVO SOFTWARE LTD., Beijing (CN)

(72) Inventors: Runsheng LIANG, Beijing (CN); Qiang ZHANG, Beijing (CN)

(73) Assignees: BEIJING LENOVO SOFTWARE LTD., Beijing (CN); LENOVO (BEIJING) CO., LTD., Beijing (CN)

(21) Appl. No.: 13/727,447

(22) Filed: Dec. 26, 2012

(30) Foreign Application Priority Data
Dec. 31, 2011 (CN) 201110459325.2

(51) Int. Cl. H05K 5/00

(52) U.S. Cl. CPC H05K 5/0086
USPC 361/679.09

(57) ABSTRACT

The present invention discloses a terminal device, comprising a first terminal part and a second terminal part, the first terminal part comprising a base part; a keyboard part on the a first region of the base part; a bracket part on a second region of the base part adjacent to the first region, wherein, the thickness of the keyboard part matches the thickness of the bracket part; a first shaft on a side of the base part away from the keyboard part and connected with the bracket part so that the bracket part can rotate clockwise or counterclockwise with respect to the first shaft; a second shaft on a side of the bracket part away from the first shaft and connected with the second terminal part, so that the second terminal part can rotate clockwise or counterclockwise with respect to the second shaft.

### CROSS REFERENCE TO RELATED APPLICATIONS

This application is based upon and claims the benefit of priority from the prior Chinese Patent Applications CN 201110459325.2, filed in the State Intellectual Property Office of the P.R.C. on Dec. 31, 2011, the disclosure of which is hereby incorporated by reference in its entirety.

### TECHNICAL FIELD

The present application relates to a terminal device, and more particularly to a terminal device with multiple usage configurations.

### BACKGROUND

In recent years, terminal devices, such as notebook computers, are becoming more and more popular. In the development process of the notebook computer, its configuration (pattern) is substantially not changed. Current notebook computers provide poor support for touching, and their usage configuration is relatively monotonic. Additionally, although terminal devices, such as pad computers, provide good support for touching and portability, the input of these terminal devices (e.g. word typing) is not convenient.

### SUMMARY

To overcome the above technical problem in the prior art, according to one aspect of the present invention, a terminal device with a first terminal part and a second terminal part is provided, the first terminal part comprising: a base part; a keyboard part, provided on a first region of the base part; a bracket part, provided on a second region of the base part adjacent to the first region, wherein, the thickness of the keyboard part matches the thickness of the bracket part; a first shaft, provided on a side of the base part away from the keyboard part and connected with the bracket part so that the bracket part can rotate clockwise or counterclockwise with respect to the first shaft; a second shaft, provided on a side of the bracket part away from the first shaft and connected with the second terminal part, wherein the second terminal part is connected to the bracket part through the second shaft and can rotate clockwise or counterclockwise with respect to the second shaft.

In one embodiment of the present invention, the bracket part comprises a computing component and a cooling component of the terminal device.

In one embodiment of the present invention, the computing component is connected to the keyboard part through a printed circuit in the first shaft; and the computing component is connected to the second terminal part through a printed circuit in the second shaft.

In one embodiment of the present invention, the computing component comprises as least a processing unit, a storage unit, and a motherboard unit; and the cooling component comprises at least one of a heat sink or a fan.

In one embodiment of the present invention, the second terminal part is a display screen of the terminal device.

In one embodiment of the present invention, the terminal device has at least a pad usage configuration, a notebook usage configuration, a desktop pad usage configuration, and a pad usage configuration having a support based on the relative position relationship between the bracket part and the base part and the relative position relationship between the second terminal part and the bracket part.

In one embodiment of the present invention, wherein in the pad usage configuration, the lower surface of the bracket part overlaps with the base part. The second terminal part is placed flat on the bracket part and the keyboard part; and the lower surface of second terminal part overlaps with the upper surface of the bracket part and the keyboard.

In one embodiment of the present invention, wherein in the notebook usage configuration, the bracket part inclines with respect to the base part to support the second terminal part. There is a predetermined angle between the second terminal part and the keyboard part.

In one embodiment of the present invention, wherein in the desktop pad usage configuration, the bracket part inclines with respect to the base part, so that the second shaft has a predetermined height; the second terminal part is parallel with the keyboard part.

In one embodiment of the present invention, wherein in the pad usage configuration having a support, the bracket part inclines with respect to the base part to support the second terminal part; and the lower surface of the second terminal part overlaps with the upper surface of the bracket part.

In one embodiment of the present invention, the size of the second terminal part matches the size of the base part.

In one embodiment of the present invention, the second terminal part is detachably connected with the second shaft. When the second terminal part is detached from the second shaft, the second terminal part alone is used as a tablet computer.

In one embodiment of the present invention, a third shaft, is further provided on the base part on the side away from the keyboard part, and can rotate clockwise or counterclockwise with respect to the plane of the base part, wherein the first shaft is provided on the third shaft.

In one embodiment of the present invention, the width of the bracket part is less than the length of the bracket part.

In one embodiment of the present invention, a fourth shaft is further provided on the second shaft; and the second terminal part is connected with the second shaft through the fourth shaft.

In one embodiment of the present invention, the second shaft and the fourth shaft are vertical to each other. The second terminal part can rotate clockwise or counterclockwise with respect to the fourth shaft.

With the above configuration, the terminal device, according to embodiments of the present invention, has a variety of usage configurations and can flexibly switch among the above described usage configurations, and therefore the terminal device, according to embodiments of the present invention, can easily meet different usage requirements of users. In addition, since the computing component and the cooling component are provided in the bracket part of the terminal device, and when the device (e.g., the notebook configuration) is used, the bracket part will be lifted high so as to support the display screen (the second terminal part) of the terminal device, thereby the bracket part can be in full contact with the surrounding air to enhance the heat dissipation. Further, since in this case the bracket part neither overlaps with the base part nor overlaps with the display screen, a large amount of heat will not be transferred to the base part or the second terminal part. Therefore, the user will not feel that the terminal device 1 is hot when using it.

### BRIEF DESCRIPTION OF THE DRAWINGS

FIG. 1 is a diagram illustrating one configuration of the terminal device according to an embodiment of the present invention;

FIG. 2 is a diagram illustrating another configuration of the terminal device according to an embodiment of the present invention;

FIG. 3 is a diagram illustrating yet another configuration of the terminal device according to an embodiment of the present invention; and

FIG. 4 is a diagram illustrating yet another configuration of the terminal device according to an embodiment of the present invention.

### DETAILED DESCRIPTION OF THE PREFERRED EMBODIMENTS

Each embodiment of the present invention will be described with reference to the accompanying drawings. It should be noted that, in the drawings, the same reference will be given to the parts having substantially the same or similar structures and functions and the repeated descriptions thereof will be omitted.

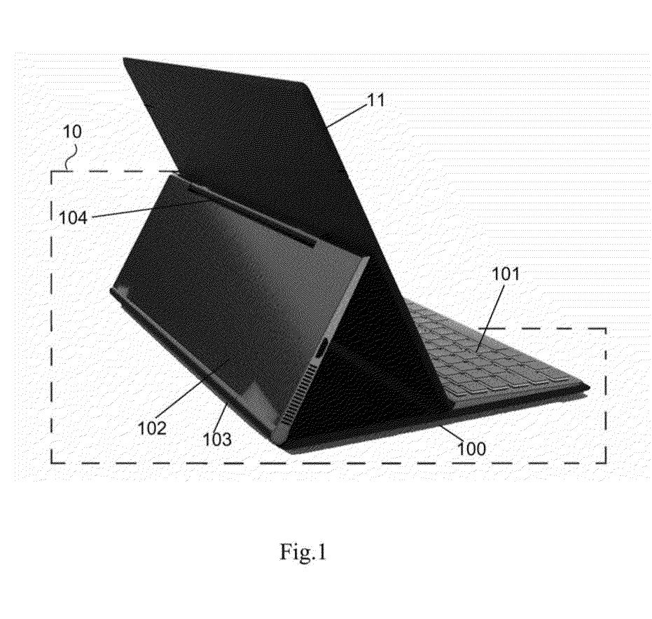

FIG. 1 is a schematic diagram illustrating the configuration of the terminal device according to an exemplary embodiment of the present invention.

As shown in FIG. 1, the terminal device 1, according to an exemplary embodiment of the present invention, may comprise a first terminal part (“or a first terminal element”) 10 and a second terminal part (“or a second terminal part”) 11. Here, the first terminal part 10 can be used as the host part of the terminal device 1, while the second terminal part 11 may be used as a display screen of the terminal device (such as a display screen having a touch function). The term “part” in the specification is intended as one characterization, which there are other characterizations, such as “element”.

Specifically, according to an embodiment of the present invention, the first terminal part 10 may further comprise: a base part 100, a keyboard part 101, a bracket part 102, a first shaft 103, and a second shaft 104.

The base part 100 may be used as the base of the terminal device 1 and can be implemented by any plastic, metallic materials or mixtures thereof. Herein, components, such as a keyboard part 101 and a bracket part 102 and the like, can be provided on the base part 100. In addition, the base part 100 can also accommodate batteries for providing power to the keyboard part 101 and the bracket part 102, and an AC/DC power interface can also be provided in the base part 100.

The keyboard part 101 may be provided in the first region of the base part 100 (e.g., on the right side region as shown in FIG. 1) and can be implemented by any type of keyboard.

The bracket part 102 may be provided in a second region of the base part 100 adjacent to the first region. Here, the first region can be adjacent to the second region and occupy substantially the whole of the upper surface of the base part 100. Here, according to one embodiment of the present invention, the bracket part 102 is substantially as wide as the base part 100. In addition, the thickness of the keyboard part 101 may also match the thickness of the bracket part 102. Specifically, the thickness of the keyboard part 101 may be the same with that of the bracket part 102, so that when the bracket part 102 lies flat on the base part 100, the bracket part 102 is as high as the keyboard part 101, so the second terminal part (display part) can be placed flat on the bracket part 102 and the keyboard part 101. In addition, the thickness of the keyboard part 101 and the thickness of the bracket part 102 may have the same slope, and the thicknesses of the adjacent places of the two are substantially the same, so that the second terminal part 11 can also be placed flat on the inclined surface formed by the upper surfaces of the bracket part 102 and the keyboard part 101 and any side or part of the second terminal part 11 will not tilt.

The first shaft 103 may be fixed on the base part 100 and can rotate clockwise or counterclockwise with respect to its axis. Specifically, the first shaft 103 can be provided on a side of the base part 100 away from the keyboard part 101, namely, on the edge of the side away from the keyboard part 101. Herein, the first shaft 103 may be connected with the bracket part 102, by, such as, plugging or fixing. In this case, since the first shaft 103 is connected to the bracket part 102, and the first shaft 103 can rotate with respect to its axis. Therefore, the bracket part 102 can rotate clockwise or counterclockwise with respect to the first shaft 103.

The second shaft 104 may be fixed to the bracket part 102 on the side away from the first shaft 103, that is, when the bracket part 102 is placed flat on the base part 100, the second shaft 104 is adjacent to the keyboard part 101, and the second shaft 104 can rotate clockwise or counter-clockwise with respect to its axis. According to the embodiment of the present invention, the second shaft 104 may be connected to the second terminal part 11 by plugging or a fixing. In this case, the second terminal part (display part) 11 is connected to the bracket part 102 by the second shaft 104 and rotates clockwise or counterclockwise with respect to the second shaft 104. Here, the second terminal part 11 may be made of any kind of thin screen.

Further, according to one embodiment of the present invention, the bracket part 102 shown in FIG. 1 is hollow and the bracket part 102 may comprise computing components and cooling components of the terminal device 1. Here, the computing component may comprise at least a processing unit of the terminal device 1 (any processor), a storage unit (memory, hard disk, solid state disk, etc.), as well as a motherboard unit. That is, the functional modules relating to computation and processing and having a large amount of heat to dissipate are integrated in the bracket part 102. In addition, cooling components, such as heatsinks, fans and the like can be arranged in the bracket part 102. Specifically, cooling components, such as heatsinks, fans and the like can be arranged near the chips or modules having high heat dissipations. Here, since the bracket part 102 as described above is as wide as the base part 100 and occupies relatively a large area, it is easy to arrange the above computing components and the cooling components in the bracket part 102 described above.

Here, it should be noted that the thickness of the keyboard part 101 and the thickness of the bracket part 102 can be determined according to the performance of the terminal device 1. For example, if the performance of the terminal device 1 is high, the volume of the computing components is large and it needs a relatively large cooling component for cooling. In this case, the thickness of the bracket part 102 can be increased so that the bracket part 102 can accommodate the larger computing components and the cooling components, and the thickness of the keyboard 101 is adjusted so that the thicknesses of the two can match each other. In addition, in the case that the performance of the terminal device 1 is not required, the thickness of the bracket part 102 can be reduced so that the bracket part 102 can be thinner, and a thin keyboard section 101 can be correspondingly used so as to match the thicknesses of the two.

In the case that the bracket part 102 comprises computing components and cooling components of the terminal device 1, as the computing component needs to connect with the display screen and the input/output unit of the terminal device 1, the computing component in the bracket part 102 is connected to the keyboard part 101 by a flexible printed circuit (FPC) arranged in the first shaft 103, and the computing component is connected to the second terminal part (display part) 11 through a flexible printed circuit (FPC) arranged in the second shaft 104. Here, the first shaft 103 and the second shaft 104 may be hollow, and the flexible printed circuits hereby can be arranged in the first shaft 103 and second shaft 104. Herein, since those skilled in the art are familiar with the line configurations of the flexible printed circuits described above, so the detailed description about them is omitted herein.

The structure of the terminal device 1, according to an embodiment of the present invention, is described above. Herein, since the bracket part 102 can rotate with respect to the first shaft 103 and the second terminal part 11 can rotate with respect to the second shaft 104, the terminal device 1, according to the embodiment of the present invention, may have different usage configurations. For example, based on the relative position relationship between the bracket part 102 and the base part 101 and the relative position relationship between the second terminal part 11 and the bracket part 102, the terminal device 1 may at least have the pad usage configuration, the notebook usage configuration, the desktop pad usage configuration, as well as the pad usage configuration having a support and the like.

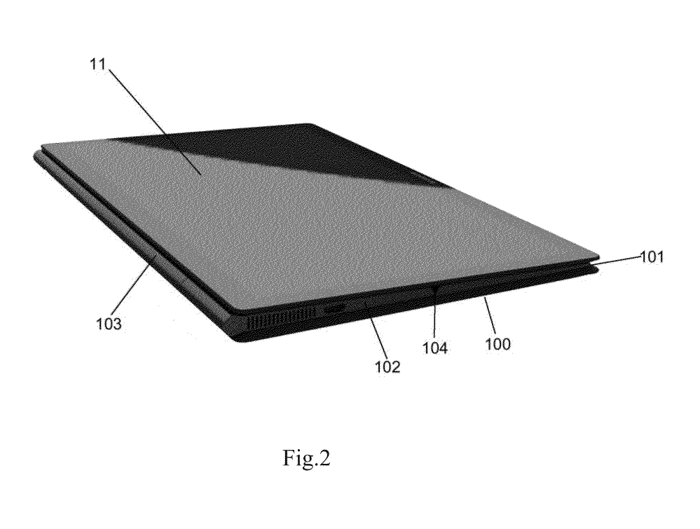

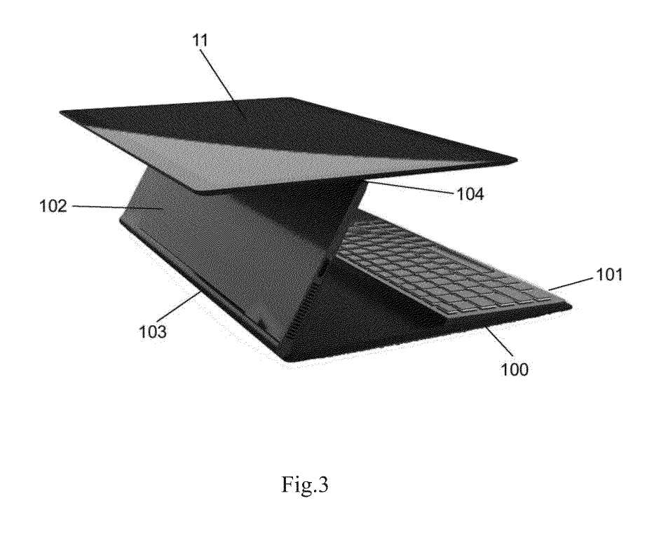

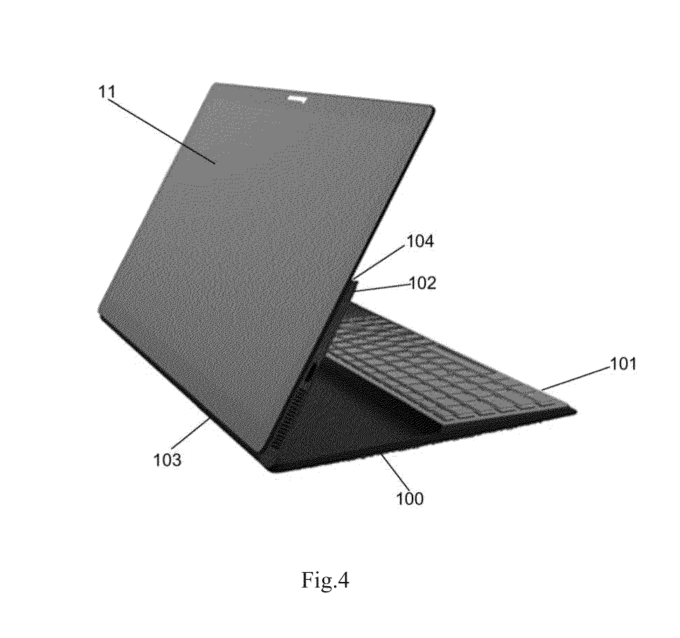

With reference to FIGS. 1 to 4, the different usage configurations of the terminal device 1, according to an embodiment of the present invention, are described below. Wherein, FIG. 1 illustrates the notebook usage configuration of the terminal device 1. FIG. 2 illustrates the pad usage configuration of the terminal device 1. FIG. 3 illustrates the desktop pad usage configuration of the terminal device 1, and FIG. 4 illustrates the pad usage configuration of terminal device 1 having a support.

An usage configuration of the terminal device, according to an embodiment of the present invention, will be described with reference to FIG. 1 below.

In the notebook usage configuration, as shown in FIG. 1, the bracket part 102 can rotate about the first shaft 103 clockwise or counterclockwise until the bracket part 102 is inclined with respect to the base part 101 to support the second terminal part 11. Specifically, according to one embodiment of the present invention, the bracket part 102 can be rotated so that the angle between the bracket part 102 and the base part 100 is in a range from 0 to 135 degrees in order to support the second terminal part (display screen) 11.

For example, as shown in FIG. 1, when the angle between the bracket part 102 and the base part 100 is less than 90 degrees, the bracket part 102 inclines to the keyboard part 101 to support the second terminal part 11. In this case, the second terminal part 11 can be rotated so that the upper surface of the second terminal part 11, i.e. the front surface of the display screen, is toward the keyboard part 101 and has a predetermined angle (e.g. larger than or equal to 90 degrees) with the keyboard part 101 so as to have the notebook configuration.

Further, the present invention is not limited thereto. When the angle between the bracket part 102 and the base part 100 is equal to 90 degrees, the bracket part 102 is vertical to the base part 100. In this case, it is possible to rotate the second terminal part 11, so that the upper surface of the second terminal part 11, i.e. the front surface of the display screen is toward the keyboard part 101 and has a predetermined angle with the keyboard part 101 (e.g., large than or equal to 90 degrees) to have the notebook configuration. In addition, when the angle between the bracket part 102 and the base part 100 is greater than 90 degrees, the bracket part 102 inclines away from the keyboard section 101. In this case, it is possible to rotate the second terminal part 11, so that the upper surface of the second terminal part 11 is toward the keyboard part 101 and has a predetermined angle with the keyboard part 101 (e.g., greater than or equal to 90 degrees) so as to have the notebook configuration.

It should be noted that the first shaft 103 or the second shaft 104 may have a predetermined damping coefficient, so that the first shaft 103 or the second shaft 104 will not be easily rotated so as to provide a good support. Furthermore, a locking mechanism (e.g., snap-fit) may be provided for the first shaft 103 or the second shaft 104 in the pre-set rotation position (corresponding to the notebook configuration) so that when the first shaft 103 or the second shaft 104 is rotated to the preset rotation position, the first shaft 103 or the second shaft 104 can be locked and the terminal device 1 has the notebook configuration

Another usage configuration of the terminal device, according to an embodiment of the present invention, will be described below with reference to FIG. 2. FIG. 2 is a diagram illustrating another configuration of the terminal device, according to an exemplary embodiment of the present invention.

As shown in FIG. 2, in the pad usage configuration, the bracket part 102 is rotated so that the bracket part 102 is put flat on the base part 100. In the state that the bracket part 102 is put flat on the base part 100, a surface (hereinafter referred to as “lower surface”) of the bracket part 102 overlaps with the base part 100, that is, overlaps with the upper surface of the base part. As described above, since the thickness of the bracket part 102 matches the thickness the keyboard of part 101, and the second terminal part 11 (e.g., the touch display screen) can clockwise or counterclockwise rotate with respect to the second shaft 104 provided on the bracket part 102. Therefore, in a state where the bracket part 102 is placed flat on the base part 100, the second terminal part 11 may be put flat on the bracket part 102 and the keyboard part 101.

In this case, the lower surface of the second terminal part 11 (e.g., the back of the touch display screen) overlaps with the upper surface of the bracket part 102 and the keyboard part 101. Here, the size of the second terminal part 11 can be suitably selected so that the size of the second terminal part 11 is the same as or approximates to the size of the base part 100 to cover the bracket part 102 and the keyboard part 101. Here, in the case that the second terminal part 11 is a touch display screen, the terminal device 1, in the case as shown in FIG. 1, can be used as a pad computer.

Another usage configuration of the terminal device, according to an embodiment of the present invention, is described below with reference to FIG. 3. FIG. 3 is a diagram illustrating another configuration of the terminal device, according to an exemplary embodiment of the present invention.

As shown in FIG. 3, in the desktop pad usage configuration, the bracket part 102 inclines with respect to the base part 100 so that the second shaft 103 has a predetermined height. Additionally, the second terminal part 11 (e.g., the touch display screen) is parallel with the keyboard part 101.

Specifically, the bracket part 102 can be rotated clockwise or counterclockwise about the first shaft 103, until the bracket part 102 inclines with respect to the base part 100 to support the second terminal part 11. Here, for example, as shown in FIG. 3, when the angle between the bracket part 102 and the base part 100 is less than 90 degrees, the bracket part 102 inclines towards the keyboard part 101 to support the second terminal part 11. In this case, since the bracket part 102 inclines with respect to the base part 100, and the second shaft 104 is provided in the bracket part 102 on the side away from the first shaft 103, the second shaft 104 has a predetermined height. Here, the height of the second shaft 102 is determined by the radius of the rotation of the bracket part 102 with respect to the first shaft 103 and the angle between the bracket part 102 and the base part 100. In addition, the second terminal part 11 is rotated to be parallel with the keyboard part 101 so as to have the usage configuration. Herein, the lower surface of the second terminal part 11 in parallel with the keyboard part 101 (e.g., the back surface of the touch display screen) faces the keyboard part 101.

Further, the present invention is not limited thereto. When the angle between the bracket part 102 and the base part 100 is equal to 90 degrees, the bracket part 102 is vertical to the base part 100. In this case, the second terminal part 11 can be rotated to parallel with the keyboard part 101 to be in the desktop pad usage configuration. In addition, when the angle between the bracket part 102 and the base part 100 is greater than 90 degrees, the bracket part 102 inclines away from the keyboard part 101. In this case, the second terminal part 11 can be rotated to parallel with the keyboard part 101 to be in the desktop pad usage configuration.

It should be noted that the first shaft 103 or the second shaft 104 may have a predetermined damping coefficient, so that the first shaft 103 or the second shaft 104 will not be easily rotated to provide a good support. Additionally, a locking mechanism (e.g., snap-fit), may be provided by the first shaft 103 or the second shaft 104 in a pre-set rotation position (corresponding to the desktop pad configuration), so that when the first shaft 103 or the second shaft 104 is rotated to the preset position, the first shaft 103 or the second shaft 104 can be locked.

In this usage configuration, since the second shaft 104 has a predetermined height, even if the terminal device 1 is placed on the bed, owing to the higher height of the touch display screen of the second terminal part 11, the user can easily operate the terminal device 1 without leaning, thereby enhancing the user's usage experience.

Another usage configuration of the terminal device, according to an embodiment of the present invention, is described below with reference to FIG. 4. FIG. 4 is a diagram illustrating another configuration of the terminal device, according to an exemplary embodiment of the present invention.

As shown in FIG. 4, in the pad usage configuration having a support, the bracket part 102 can be rotated clockwise or counterclockwise with respect to the first shaft 103, until the bracket part 102 inclines with respect to the base part 100 to the support the second terminal part 11. Specifically, according to one embodiment of the present invention, the bracket part 102 can be rotated so that the angle between the bracket part 102 and the base part 100 is between 20 to 70 degrees to support the second terminal part 11 (such as the touch display screen). In addition, in this usage configuration, the lower surface of the second terminal part 11 overlaps with the upper surface of the bracket part 102.

For example, as shown in FIG. 4, when the angle between the bracket part 102 and the base part 100 is between 20 and 70 degrees, the bracket part 102 inclines towards the keypad part 101 to support the second terminal part 11. In this case, the second terminal part 11 can be rotated, so that at least a part of the lower surface of the second terminal part 11 (e.g., the back surface of the touch display screen) overlaps with the upper surface of the bracket part 102.

In this usage configuration, if the terminal device 1 is put on the user's leg or on the desk, the second terminal part 11 can face to the user, and have a certain inclination angle. In this case, the user can operate the terminal device 1 without having to hold the terminal device 1, and can rotate the bracket part 102 to adjust the inclination angle of the second terminal part 11 in order to adapt to the different postures of the user, thereby enhancing the user's experience.

Different usage configurations of the terminal device 1 according to the embodiment of the present invention are described above. Here, the terminal device according to the embodiment of the present invention has a variety of usage configurations and can flexibly switch among the different usage configurations by rotating the bracket part 102 and a second terminal part 11. Therefore, the terminal device according to an embodiment of the present invention can easily meet the different requirements of the user. In addition, the bracket part 102 and the second terminal part 11 can be flexibly adjusted so that the terminal device 1 may have other usage configurations. In addition, since the computing component and cooling component are built in the bracket part 102 of the terminal device 1, and when the terminal device 1 is used (e.g., in the notebook configuration, the desktop pad configuration, or the pad configuration with a support), the bracket part 102 lifts high to support the second terminal part of the terminal device (e.g., the touch display screen), and the bracket part 102 can thereby be in full contact with the surrounding air in order to enhance heat dissipation. Furthermore, since in this case the bracket part 102 neither overlaps with the base part 100 nor overlaps with the second terminal part 11, the heat will not be transfered in large amounts to the base part or the second terminal part. Therefore, the user will not feel that the terminal device 1 is hot when using it.

In the above description, the terminal device according to an embodiment of the present invention is described. However, the present invention is not limited thereto.

For example, according to another embodiment of the present invention, the second terminal part 11 may be a pad and can be detachably connected to the second shaft 104. Specifically, the second terminal part 11 can be detachably connected to the second shaft 104 by plugging. For example, it is possible to provide a slot on the second terminal part 11, a plug on the second shaft 104 and a flexible printed circuit in the slot of the second terminal part 11 and the plug of the second shaft 104, so that the electrical connection between the second terminal part 11 and the second shaft 104 is ensured and the second terminal part 11 is allowed to connect with the computing component of the bracket part 102 through the second shaft 104.

Here, when the second terminal part 11 separates from the second shaft 104, the second terminal part 11 itself is used as a pad. In addition, when the second terminal part 11 is connected to the second shaft 104, the second terminal part 11 can be used only as a display screen of the terminal device 1. That is, when the second terminal part 11 is connected with the second shaft 104, the internal computing unit in the second terminal part 11 does not work, and the display screen of the second terminal part 11 displays images or videos based on the data from the computing component of the bracket part 102.

In addition, according to another embodiment of the present invention, the terminal device 1 may further comprise a third shaft (not shown). The third shaft is provided on the base part 100 on the side away from the keyboard part 101 and can rotate clockwise or counterclockwise with respect to the plane of the base part 100. In the present embodiment, the first shaft 103 can be provided on the third shaft.

In this case, since the third shaft can rotate clockwise or counterclockwise with respect to the plane of the base part 100 and the first shaft 103 is provided on the third shaft, in addition to rotating with respect to the first shaft 103, the bracket part 102 can also rotate clockwise or counterclockwise with respect to the plane of the base part 100, so that the second terminal part 11 can also rotate clockwise or counterclockwise with respect to the plane of the base part 100, thereby further increasing usage configuration of the terminal device 1 and satisfying the different usage demands for users.

In the present embodiment, the width of the bracket part 102 is preferably less than the length of the bracket part. Here, the width of the bracket part 102 refers to the side length in the direction along the first shaft 103, while the length of the bracket part 102 refers to the side length of the bracket part in the direction from the first shaft 103 to the keyboard part 101 (i.e. the side length in a direction orthogonal to the width direction). The purpose is to prevent the situation wherein when the bracket part 102 rotates clockwise or counterclockwise with respect to the plane of the base part 100, the bracket part 102 will be blocked by the keyboard section 101. In addition, in this case, the width of the bracket part is usually less than the width of the second region, so components, such as a speaker or a USB interface, can be provided in the remaining region of the second region, i.e. on both sides of the second region of the base part 100.

In addition, according to another embodiment of the present invention, the terminal device 1 may further comprise a fourth shaft (not shown). The fourth shaft may be provided on the second shaft 104, and the second shaft 104 is vertical to the fourth shaft. In this case, the second terminal part 11 is connected to the second shaft 104 through the fourth shaft.

In this case, since the fourth shaft can rotate with respect to its axis and the second shaft 104 is vertical to the fourth shaft, the second terminal part 11 can not only rotate clockwise or counterclockwise with respect to the second shaft 104, but also rotate clockwise or counterclockwise with respect to the fourth shaft, which is vertical to the second shaft 104. That is, the second terminal part 11 may rotate with respect to the fourth shaft in parallel with the second shaft 104.

As described above, various embodiments of the present invention have been specifically described above, but the present invention is not limited thereto. It should be understood by those skilled in the art that various modifications, combinations, sub-combinations, or replacements can be carried out according to the designing requirements or other factors, which, however, fall within the scope of the appended claims and their equivalents.

What is claimed is:

1. A terminal device, comprising:
a first terminal part and a second terminal part, the first terminal part comprising
a base part;
a keyboard part, provided on the a first region of the base part;
a bracket part, provided on a second region of the base part adjacent to the first region, wherein, the thickness of the keyboard part matching the thickness of the bracket part;
a first shaft provided on a side of the base part away from the keyboard part and connected with the bracket part in which the bracket part is able to rotate clockwise or counterclockwise with respect to the first shaft;
a second shaft provided on a side of the bracket part away from the first shaft and connected with the second terminal part; and
wherein the second terminal part is connected to the bracket part through the second shaft, and is rotatable clockwise or counterclockwise with respect to the second shaft.

2. The terminal device of claim 1, wherein the bracket part comprises a computing component and a cooling component of the terminal device.

3. The terminal device of claim 2, wherein
the computing component is connected to the keyboard part through a printed circuit provided in the first shaft; and
the computing component is connected to the second terminal part through a printed circuit provided in the second shaft.

4. The terminal device of claim 2, wherein
the computing component comprises as least a processing unit, a storage unit and a motherboard unit; and
the cooling component comprises at least one of a heat sink or a fan.

5. The terminal device of claim 1, wherein the second terminal part is a display screen of the terminal device.

6. The terminal device of claim 5, wherein
the terminal device has at least a pad usage configuration, a notebook usage configuration, a desktop pad usage configuration and a pad usage configuration having a support based on the relative position relationship between the bracket part and the base part and the relative position relationship between the second terminal part and the bracket part.

7. The terminal device of claim 6, wherein, in the pad usage configuration,
the lower surface of the bracket part overlaps with the base part;
the second terminal part is put flat on the bracket part and the keyboard part; and
the lower surface of second terminal part overlaps with the upper surface of the bracket part and the keyboard part.

8. The terminal device of claim 6, wherein in the notebook usage configuration,
the bracket part inclines with respect to the base part to support the second terminal part; and
there is a predetermined angle between the upper surface of the second terminal part and the keyboard part.

9. The terminal device of claim 6, wherein in the desktop pad usage configuration,
the bracket part inclines with respect to the base part, so that the second shaft has a predetermined height;
the second terminal part is parallel with the keyboard part.

10. The terminal device of claim 6, wherein in the pad usage configuration having a support,
the bracket part inclines with respect to the base part to support the second terminal part; and
the lower surface of the second terminal part overlaps with the upper surface of the bracket part.

11. The terminal device of claim 5, wherein the size of the second terminal part matches the size of the base part.

12. The terminal device of claim 5, wherein
the second terminal part is detachably connected with the second shaft; and
when the second terminal part is detached from the second shaft, the second terminal part alone is used as a pad.

13. The terminal device of claim 1, further comprising:
a third shaft, provided in the base part on the side away from the keyboard part, and can rotate clockwise or counterclockwise with respect to the plane of the base part,
wherein the first shaft is provided on the third shaft.

14. The terminal device of claim 13, wherein the width of the bracket part is less than the length of the bracket part.

15. The terminal device of claim 1, further comprising:
a fourth shaft, provided on the second shaft; and
the second terminal part is connected with the second shaft through the fourth shaft.

16. The terminal device of claim 15, wherein
the second shaft and the fourth shaft are vertical to each other; and
the second terminal part can rotate clockwise or counterclockwise with respect to the fourth shaft.
